(19) United States
(12) Patent Application Publication
(10) Pub. No.: US 2018/0308876 A1
(43) Pub. Date: Oct. 25, 2018

(54) ACTIVE SWITCH ARRAY SUBSTRATE, MANUFACTURING METHOD THEREFOR, AND DISPLAY PANEL USING THE SAME

(71) Applicants: HKC Corporation Limited, Shenzhen City, Guangdong (CN); Chongqing HKC Optoelectronics Technology Co., Ltd., Chongqing (CN)

(72) Inventor: Chung-Kuang CHIEN, Chongqing (CN)

(21) Appl. No.: 15/555,912

(22) PCT Filed: May 19, 2017
(86) PCT No.: PCT/CN2017/085158

§ 371 Date: Sep. 5, 2017

(30) Foreign Application Priority Data
Apr. 20, 2017 (CN) 201710263554.4

(51) Int. Cl. H01L 27/12; H01L 21/285; H01L 29/66; H01L 21/3213; H01L 29/417; H01L 21/02; H01L 29/786; H01L 23/29; H01L 23/31; G02F 1/1335; G02F 1/1368; H01L 29/227; H01L 21/443; G02F 1/1333; C23C 16/50

(52) U.S. Cl. CPC H01L 27/1262; G02F 2202/10; H01L 29/66765; H01L 21/32133; H01L 29/41733; H01L 21/02274; H01L 29/78669; H01L 29/7869; H01L 23/291; H01L 23/3171; G02F 1/133514; G02F 1/1368; H01L 29/66969; H01L 29/227; H01L 21/443; H01L 27/1248; H01L 27/1222; H01L 27/1225; G02F 1/133345; C23C 16/50; H01L 21/02164; H01L 21/0217; G02F 2202/103; H01L 21/2855

(57) ABSTRACT

This application relates to an active switch array substrate, a manufacturing method therefor, and a display panel using same. The active switch array substrate includes: a substrate; a gate electrode, configured on the substrate; an insulation protection layer, configured on the gate electrode; a semiconductor active layer, configured on the gate electrode and the insulation protection layer; an active layer channel, formed on a dent surface layer above the middle of the semiconductor active layer; a source electrode, configured at one side of the semiconductor active layer and forming ohmic contact with the semiconductor active layer; a drain electrode, configured at the other side of the semiconductor active layer and forming ohmic contact with the semiconductor active layer; and a passivation layer, covering the semiconductor active layer, the source electrode, and the drain electrode.

### BACKGROUND

### Technical Field

This application relates to an active switch array substrate, a manufacturing method therefor, and a display panel using same, and in particular, to a method for improving a process of manufacturing a passivation layer by means of plasma-assisted chemical vapor deposition by an active switch array substrate.

### Related Art

A thin film transistor (TFT) is an active switch array substrate, is configured to control imaging of a display panel in a liquid crystal display screen, and is an indispensable main component.

An active switch array substrate is configured with a source electrode and a drain electrode. When a current on the source electrode at a left side flows to the drain electrode at a right side, the current needs to pass through an active layer channel formed above a semiconductor active layer. When a drive voltage is applied to a gate electrode located below the semiconductor layer, an induced electric field is generated in the semiconductor layer to control opening and closing of the active layer channel. This is a working principle of the active switch array substrate. The foregoing active switch array substrate is manufactured on a glass substrate. This process requires use of a semiconductor process device of physical vapor deposition (PVD), chemical vapor deposition (CVD), or the like. When a plasma-assisted chemical vapor deposition machine is used to form a passivation layer of the active switch array substrate, if process conditions of the machine are not most appropriately adjusted, the most significant active layer channel above the active switch array substrate may be damaged due to ion bombardment generated when the plasma-assisted chemical vapor deposition machine performs deposition. Therefore, the subthreshold swings of the active layer channel and the mobility of an electronic crossing channel are reduced. As a result, component characteristics of the entire active switch array substrate are affected, and the active layer channel formed by a transparent semiconductor material of a zinc oxide series (IZO, IGZO, AZO) suffers the greatest impact. This problem is to be overcome in process technologies.

### SUMMARY

To resolve an existing process technical problem, an objective of this application is to provide a method for manufacturing an active switch array substrate, including the following steps: providing a substrate; sputtering a metal layer on the substrate, to form a gate electrode metal layer; sequentially forming an insulation protection layer, a semiconductor active layer, and an ohmic electrode metal layer on the gate electrode metal layer; etching the ohmic electrode metal layer above the middle of the semiconductor active layer, so that an active layer channel is formed on a dent surface above the middle of the semiconductor active layer, and the ohmic electrode metal layer is distinguished into a source electrode and a drain electrode at two sides of the active layer channel; and forming a passivation layer on the semiconductor active layer, the source electrode, and the drain electrode by applying a pressure in a range of 10 Pa to 15 Pa.

In an embodiment of this application, the passivation layer is formed by using a plasma-assisted chemical vapor deposition machine.

In an embodiment of this application, the plasma-assisted chemical vapor deposition machine uses argon as working gas, and the gas flow of the argon is in a range of 500 cc/min to 600 cc/min.

In an embodiment of this application, the gas flow of the argon is 550 cc/min.

In an embodiment of this application, the semiconductor active layer and the metal layer are graphically processed.

The method for resolving the foregoing technical problem in this application is performing deposition by using a high gas pressure and a high gas flow in a working chamber of the machine during deposition of the passivation layer on the active switch array substrate by using the plasma-assisted chemical vapor deposition machine. Pressure increase can shorten an active path of free molecules within a vacuum cavity and effectively reduce energy of ion bombardment, and therefore the active layer channel is not damaged. Increase of the argon (Ar) gas flow within the working chamber can more effectively completely dissociate silicomethane (SiH₄) and ammonia (NH₃) or nitrogen monoxide (N₂O), and therefore the active layer channel is not damaged. Therefore, use of the condition for the deposition process can certainly reduce damage of ion bombardment to the active layer channel within the active switch array substrate effectively, and can ensure that the active switch array substrate still has good characteristics without additionally adding process steps or costs.

To resolve the existing technical problem, another objective of this application is to provide an active switch array substrate, including: a substrate; a gate electrode, configured on the substrate; an insulation protection layer, configured on the gate electrode; a semiconductor active layer, configured on the gate electrode and the insulation protection layer; an active layer channel, formed near a dent surface layer above the middle of the semiconductor active layer, where the surface roughness of the dent surface layer is less than 10 nm; a source electrode, configured at one side of the semiconductor active layer and forming ohmic contact with the semiconductor active layer; a drain electrode, configured at the other side of the semiconductor active layer and forming ohmic contact with the semiconductor active layer; and a passivation layer, covering the semiconductor active layer, the source electrode, and the drain electrode.

In an embodiment of this application, the material of the semiconductor active layer is amorphous silicon.

In an embodiment of this application, a semiconductor material within the active switch array substrate is a transparent semiconductor material of a zinc oxide series, such as zinc oxides doped with metal indium, aluminum, or indium-gallium (IZO, AZO, IGZO).

In an embodiment of this application, a high-concentration N-type semiconductor is formed by doping phosphorous (P), arsenic (As), and stibium (Sb) on surfaces above a left side and a right side of the semiconductor active layer.

In an embodiment of this application, the material of the passivation layer is silicon nitride or silicon oxide.

To resolve the existing technical problem, another objective of this application is to provide a display panel, including: a color filter layer substrate; a liquid crystal unit; and an active switch array substrate, where the active switch array substrate includes a semiconductor active layer, an active layer channel is formed on a dent surface layer above the middle of the semiconductor active layer, and the surface roughness of the dent surface layer is less than 10 nm; the material of the semiconductor active layer is amorphous silicon; the material of the semiconductor active layer is a transparent semiconductor material of a zinc oxide series doped with metal indium, aluminum, or indium-gallium; and the material of the passivation layer is silicon nitride or silicon oxide.

By means of improvement of this application, impact of ion bombardment within the working chamber of the plasma-assisted chemical vapor deposition machine can be reduced, and it is ensured that damage is not caused to the active layer channel of the active switch array substrate during deposition of the passivation layer, thereby maintaining good original characteristics.

### BRIEF DESCRIPTION OF THE DRAWINGS

FIG. 1 is a schematic structural diagram of an active switch array substrate of this application; and

FIG. 2 is a schematic structural diagram of a working chamber of a plasma-assisted chemical vapor deposition machine used in this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions of the accompanying drawings. Therefore, the used terms about directions are used to describe and understand this application, and are not intended to limit this application.

The accompanying drawings and the description are considered to be essentially exemplary, rather than limitative. In figures, units with similar structures are represented by using a same reference number. In addition, for understanding and ease of description, a size and a thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a substrate is described to be “on” “another component”, the component may be directly on the another component, or there may be an intermediate component.

In addition, in this specification, unless otherwise explicitly described to have an opposite meaning, the word “include” is understood as including the component, but not excluding any other component. In addition, in this specification, “on” means that a component is located on or below a target component, but does not mean that the component needs to be located on top of a gravity direction.

To further describe the technical means used in this application to achieve the predetermined invention objective and effects thereof, specific implementations, structures, features, and effects of an active switch array substrate, a manufacturing method therefor, and a display panel using same provided according to this application are described in detail below with reference to the drawings and preferred embodiments.

Chemical vapor deposition is a process of reacting gaseous reactants by using various energy sources to overcome reaction activation energy barrier of a chemical reaction and forming a thin film on a substrate. The plasma activation method is also referred to as a plasma-assisted chemical vapor deposition technology (energy needed in a reaction is provided by using both heating and a plasma; because of the relatively low temperature reaction characteristics, the plasma activation method is widely used in process environments that require a relatively low temperature; for example, a process using a plasma-assisted chemical vapor deposition machine is widely used for silicon oxide, silicon nitride, and silicon oxynitride thin films in a semiconductor process. The growth mechanism of the plasma-assisted chemical vapor deposition machine is similar to the growth mechanism of a common chemical vapor deposition process, source material gas is uniformly imported into a reactor through a showerhead, and reaction gas forms a plurality of hyper-responsiveness fragments, including a large quantity of free radical molecules, by means of plasma activation. Hyper-responsiveness free radicals enter the bottom of a boundary layer by means of diffusion and gather on a surface of a heated substrate, are formed on the substrate after reaction by means of a high temperature on the surface of the substrate, and meanwhile, release a volatile by-product. The by-product penetrates through the boundary layer and is then taken away by a vacuum pump along with an airflow.

Ion bombardment is an important characteristic of the plasma-assisted chemical vapor deposition machine and is a phenomenon in which positive ions within the plasma collide towards a substrate at a relatively low level. Acceleration of positive ions at a low frequency is significant. Therefore, ion bombardment at a low frequency is stronger than ion bombardment at a high frequency. In addition, ion bombardment is enhanced when RF power is increased. Proper ion bombardment may improve thin film deposition, including increasing a thin film density, improving a step coverage, and changing a thin film stress. However, when a thin film is formed on a semiconductor material by using the plasma-assisted chemical vapor deposition machine, the ion bombardment may damage the semiconductor material if proper protection measures are not taken in advance for the semiconductor material.

In an embodiment of this application, a display panel is provided, including a color filter unit, a liquid crystal unit, and an active switch array substrate.

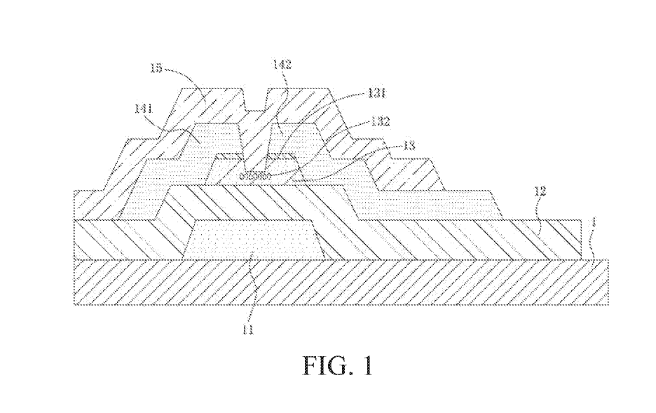

Referring to FIG. 1, FIG. 1 is a schematic structural diagram of an active switch array substrate made in this application. This application provides an active switch array substrate finished by a plasma-assisted chemical vapor deposition machine forming a passivation layer in improved manufacturing conditions, including: a substrate 1; a gate electrode 11, configured on the substrate 1; an insulation protection layer 12, configured on the gate electrode 11 and capable of performing insulation protection on the gate electrode 11; a semiconductor active layer 13, configured on an insulation protection layer 12, where an active layer channel 132 is formed near a dent surface layer above the middle of the semiconductor active layer 13; a source electrode 141, configured at one side of the semiconductor active layer 13 and forming ohmic contact with the semiconductor active layer 13; a drain electrode 142, configured at the other side of the semiconductor active layer 13 and forming ohmic contact with the semiconductor active layer 13; and a passivation layer 15, covering the semiconductor active layer 13, the source electrode 141, and the drain electrode 142 and used for insulation protection.

Further, still refer to FIG. 1. In the active switch array substrate of this application, the material of the semiconductor active layer 13 in this embodiment is amorphous silicon. In other embodiments, the material may be a transparent semiconductor material of a zinc oxide series, such as zinc oxides doped with metal indium, aluminum, or indium-gallium (IZO, AZO, IGZO). To form effective ohmic contact with the source electrode 141 and with the drain electrode 142, an N-type semiconductor material such as phosphorous (P), arsenic (As), and stibium (Sb) is used to dope on surfaces above a left side and a right side of the semiconductor active layer 13, to form an N-type semiconductor surface layer 131 having a high doping concentration, so that the semiconductor active layer 13 can form effective ohmic contact with a subsequently plated metal layer, thereby manufacturing the source electrode 141 and the drain electrode 142. When a current on the source electrode 141 at the left side flows to the drain electrode 142 at the right side, the current needs to pass through the active layer channel 132 formed above the semiconductor active layer 13. When a drive voltage is applied to the gate electrode 11 located below the semiconductor active layer 13, an induced electric field is generated in the semiconductor active layer 13 to control opening and closing of the active layer channel 132, so that the current of the source electrode 141 can flow to the drain electrode 142 and then flow to an ITO pixel electrode (not shown in the figure) connected to the drain electrode 142, to drive liquid crystal molecules in a liquid crystal display screen to rotate.

The active switch array substrate of this application is made by using plasma-assisted chemical vapor deposition, and mainly performs deposition by using a gas having a high gas pressure or a high gas flow within a working chamber of a machine, thereby manufacturing a passivation layer of the active switch array substrate. The high gas pressure refers to raising the pressure within the working chamber to be higher than 10 Pa commonly used in the industry, and the high gas flow refers to raising an argon gas flow within the working chamber to be higher than 400 cc/min commonly used in the industry. Manufacturing process steps thereof are as follows: first, sputtering a metal layer on a substrate 1; graphically processing the metal layer by means of a photoetching technology, to form a gate electrode metal layer 11; then sequentially forming an insulation protection layer 12, a semiconductor active layer 13, and an ohmic electrode metal layer on the gate electrode metal layer 11; then etching the ohmic electrode metal layer above the middle of the semiconductor active layer 13, so that an active layer channel 132 is formed on a dent surface above the middle of the semiconductor active layer 13, and the ohmic electrode metal layer is separately formed on a source electrode 141 and a drain electrode 142 at two sides of the active layer channel 13; and at last, applying a pressure in a range of 10 Pa to 15 Pa to form a passivation layer 15 on the semiconductor active layer 13, the source electrode 141, and the drain electrode 142 for insulation protection, and performing graphic processing to finish the active switch array substrate.

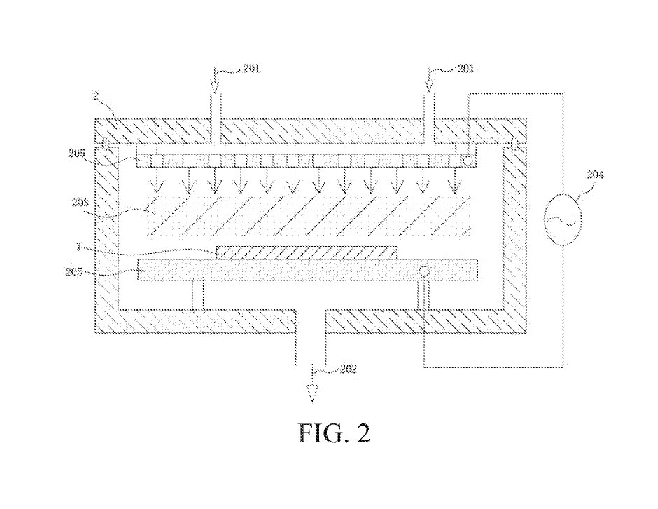

Referring to FIG. 2, FIG. 2 is a schematic structural diagram of a working chamber of a plasma-assisted chemical vapor deposition machine used in this application. After manufacturing of the source electrode 141 and the drain electrode 142, the passivation layer 15 is formed by using the plasma-assisted chemical vapor deposition machine and covers the semiconductor active layer 13, the source electrode 141, and the drain electrode 142 for insulation protection. In this embodiment, the material of the passivation layer 13 is silicon nitride or silicon oxide. When silicon nitride is selected as the passivation layer 13, silicomethane (SiH₄) or dichlorodimethylsilane (SiCl₂H₂) and ammonia (NH₃) are used as a source material gas, and the source material gas is uniformly imported into a reactor through a showerhead 201 of the working chamber 2. The working chamber 2 may extract unnecessary gas by means of an exhaust vent 202 to form a vacuum state. A method for generating a plasma 203 within a reactor is pumping a grounding radio frequency plasma source 204 into a reaction chamber between upper and lower electrodes 205. Because of relatively light weights, electrons can absorb radio frequency energy changing in an alternating manner to move back and forth at a high speed between the upper and lower electrodes 205. The electrons moving at a high speed generate elastic and inelastic collision with source material gas molecules. Inelastic collision generates transfer of electron energy to separately form complicated plasma chemical reactions such as ionization and dissociation. Source material gas SiH₄ and NH₃ may form a large quantity of hyper-responsiveness SiHₙ and NHₙ free radical molecules by means of plasma activation. Hyper-responsiveness free radical molecules gather on a surface of a heated substrate 1 by means of diffusion and form a Si—N structure after reaction by means of a high temperature on the surface of the substrate. Then the Si—N structure is converted into a silicon nitride solid product and is formed on the substrate 1, that is, the passivation layer 13 is formed.

As stated above, because the plasma-assisted chemical vapor deposition machine has characteristics of ion bombardment, which may damage the active layer channel 132 during deposition of the passivation layer 13. Therefore, the subthreshold swings of the active layer channel 132 and the mobility of an electronic crossing channel are reduced. As a result, component characteristics of the entire active switch array substrate are affected. With regard to the problem, the solution of this application is performing deposition by increasing a gas pressure within the working chamber of the machine during deposition of the passivation layer 13. An original pressure used in the working chamber is 10 Pa. When the pressure is increased to be in a range of 10 Pa to 15 Pa, an active path of free molecules within a vacuum cavity can be shortened and energy of ion bombardment can be effectively reduced, and therefore the active layer channel 132 is not damaged. The most appropriate pressure value is 15 Pa. Further, argon and hydrogen are used as carrier gas within the working chamber of the plasma-assisted chemical vapor deposition machine. In this embodiment, argon and hydrogen are combined as 10% H₂+90% Ar. When the argon gas flow within the working chamber is properly increased to be in a range of 500 cc/min to 600 cc/min, where the most appropriate flow control value is 550 cc/min, silicomethane and ammonia or nitrogen monoxide can be more effectively completely dissociated, and therefore the active layer channel 132 is not damaged and component characteristics becomes better. According to a verification measurement result of a transmission electron microscopy (TEM), the surface roughness of a surface layer above the active layer channel 132 is less than 10 nm. Use of the condition for the deposition process can effectively reduce damage of ion bombardment to the active layer channel 132 within the active switch array substrate, and can ensure that the active switch array substrate still has good characteristics without additionally adding process steps or costs.

After the foregoing improvement of process steps, this application provides a display panel with good characteristics, including a color filter unit; a liquid crystal unit; and an active switch array substrate. The active switch array substrate includes a semiconductor active layer. An active layer channel is formed on a dent surface layer above the middle of the semiconductor active layer. The surface roughness of the dent surface layer is less than 10 nm. The material of the semiconductor active layer is amorphous silicon. The material of the semiconductor active layer is a transparent semiconductor material of a zinc oxide series doped with metal indium, aluminum, or indium-gallium. The material of the passivation layer is silicon nitride or silicon oxide. The display panel provided in this application can lower impact of ion bombardment within the working chamber of the plasma-assisted chemical vapor deposition machine, and ensure that damage is not caused to the active layer channel of the internal components of the active switch array substrate during deposition of the passivation layer, thereby presenting good characteristics.

In this application, for the active switch array substrate whose process steps are defective, product characteristics of the active switch array substrate can be improved by simply changing and adjusting process parameters without additionally adding extra process steps or costs. After improvement of this application, when a subsequent product related to the active switch array substrate is developed, the product quality thereof can be improved.

Terms such as “in an embodiment” and “in various embodiments” are repeatedly used. Usually, the terms do not refer to a same embodiment; but they may also refer to a same embodiment. Words such as “comprise”, “have”, and “include” are synonyms, unless other meanings are indicated in the context.

The foregoing descriptions are merely preferred embodiments of this application, and are not intended to limit this application in any form. Although this application has been disclosed above through the preferred embodiments, the embodiments are not intended to limit this application. Any person skilled in the art can make some equivalent variations or modifications according to the foregoing disclosed technical content without departing from the scope of the technical solutions of this application to obtain equivalent embodiments. Any simple amendment, equivalent change or modification made to the foregoing embodiments according to the technical essence of this application without departing from the content of the technical solutions of this application shall fall within the scope of the technical solutions of this application.

1. A method for manufacturing an active switch array substrate, comprising the following steps:
providing a substrate;
sputtering a metal layer on the substrate, to form a gate electrode metal layer;
sequentially forming an insulation protection layer, a semiconductor active layer, and an ohmic electrode metal layer on the gate electrode metal layer;
etching the ohmic electrode metal layer above the middle of the semiconductor active layer, soan active layer channel is formed on a dent surface above the middle of the semiconductor active layer, and the ohmic electrode metal layer is distinguished into a source electrode and a drain electrode at two sides of the active layer channel; and
forming a passivation layer on the semiconductor active layer, the source electrode, and the drain electrode by applying a pressure in a range of 10 Pa to 15 Pa.

2. The method for manufacturing an active switch array substrate according to claim 1, wherein the passivation layer is formed by using a plasma-assisted chemical vapor deposition machine.

3. The method for manufacturing an active switch array substrate according to claim 2, wherein the plasma-assisted chemical vapor deposition machine uses argon as working gas.

4. The method for manufacturing an active switch array substrate according to claim 2, wherein the gas flow of the argon is in a range of 500 cc/min to 600 cc/min.

5. The method for manufacturing an active switch array substrate according to claim 4, wherein the gas flow of the argon is 550 cc/min.

6. The method for manufacturing an active switch array substrate according to claim 1, further comprising graphically processing the semiconductor active layer and the metal layer.

7. An active switch array substrate, comprising:
a substrate;
a gate electrode, configured on the substrate;
an insulation protection layer, configured on the gate electrode;
a semiconductor active layer, configured on the gate electrode and the insulation protection layer;
an active layer channel, formed on a dent surface layer above the middle of the semiconductor active layer, wherein the surface roughness of the dent surface layer is less than 10 nm;
a source electrode, configured at one side of the semiconductor active layer and forming ohmic contact with the semiconductor active layer;
a drain electrode, configured at the other side of the semiconductor active layer and forming ohmic contact with the semiconductor active layer; and
a passivation layer, covering the semiconductor active layer, the source electrode, and the drain electrode.

8. The active switch array substrate according to claim 7, wherein the material of the semiconductor active layer is amorphous silicon.

9. The active switch array substrate according to claim 7, wherein the material of the semiconductor active layer is a transparent semiconductor material of a zinc oxide series doped with metal indium, aluminum, or indium-gallium.

10. The active switch array substrate according to claim 7, wherein the material of the passivation layer is silicon nitride.

11. The active switch array substrate according to claim 7, wherein the material of the passivation layer is silicon oxide.

12. A display panel, comprising:
a color filter layer substrate;
a liquid crystal unit; and
an active switch array substrate, wherein the active switch array substrate comprises a semiconductor active layer, an active layer channel is formed on a dent surface layer above the middle of the semiconductor active layer, and the surface roughness of the dent surface layer is less than 10 nm.

13. The display panel according to claim 12, wherein the material of the semiconductor active layer is amorphous silicon.

14. The display panel according to claim 12, wherein the material of the semiconductor active layer is a transparent semiconductor material of a zinc oxide series doped with metal indium, aluminum, or indium-gallium.

15. The display panel according to claim 12, wherein the material of the passivation layer is silicon nitride or silicon oxide.
